(19) United States
(12) Patent Application Publication
(10) Pub. No.: US 2022/0005850 A1
(43) Pub. Date: Jan. 6, 2022

(54) PHOTODIODE INSULATION

(71) Applicant: STMicroelectronics (Crolles 2) SAS, Crolles (FR)

(72) Inventors: Alain INARD, Saint Nazaire Les Eymes (FR); Marios BARLAS, Grenoble (FR)

(73) Assignee: STMicroelectronics (Crolles 2) SAS, Crolles (FR)

(21) Appl. No.: 17/363,345

(22) Filed: Jun. 30, 2021

(30) Foreign Application Priority Data
Jul. 3, 2020 (FR) 2007058

(51) Int. Cl. H01L 27/146; H01L 31/0232

(52) U.S. Cl. CPC H01L 27/1463; H01L 27/14683; H01L 31/0232; H01L 27/14643

(57) ABSTRACT

An optoelectronic device includes a photodiode. At least a portion of an active area of the photodiode is separated from a neighboring photodiode by a first wall including a conductive core and an insulating sheath and by a second optical insulation wall. The first wall and second optical insulation wall further extend parallel to each other and separate the active area from a memory area of the photodiode.

### PRIORITY CLAIM

This application claims the priority benefit of French Application for Patent No. 2007058, filed on Jul. 3, 2020, the content of which is hereby incorporated by reference in its entirety to the maximum extent allowable by law.

### TECHNICAL FIELD

The present disclosure generally concerns optoelectronic devices and, more particularly, optoelectronic devices comprising photodiodes.

### BACKGROUND

Optoelectronic devices are, for example, devices generating images representative of a scene. Optoelectronic devices, for example, comprise pixels, each pixel comprising at least one photodiode. Each photodiode comprises an active area, that is, an area generating electric charges when it receives radiation. The quantity of generated charges, depending on the received quantity of illumination, that is, of radiation, and on the sensitivity of the material, is representative of a portion of the scene.

The operation of a photodiode comprises two phases, a first phase of charge generation and a second phase of reading of the quantity of generated charges. During the first phase, the radiation received by the photodiode generates charges which are stored in the active area of the photodiode or in memory areas. During the second phase, the memory areas are read from, that is, the device generates a voltage representative of the quantity of charges in the memory areas.

There is a need in the art to address all or some of the drawbacks of known optoelectronic devices.

### SUMMARY

An embodiment provides an optoelectronic device comprising at least one photodiode, at least a portion of an active area of each photodiode being separated from a neighboring photodiode by a first wall comprising a conductive core and an insulating sheath and by a second optical insulation wall.

Another embodiment provides a method of manufacturing an optoelectronic device comprising forming at least one photodiode, and forming, in an active area of each photodiode, a first conductive wall and a second optical insulation wall separating at least a portion of the active area from a neighboring photodiode.

According to an embodiment, the method comprises simultaneously forming first trenches in a substrate, from a first surface of the substrate, at the locations of the first walls, and forming second trenches in the substrate, from the first surface of the substrate, at the locations of the second walls.

According to an embodiment, the method comprises filling the first and second trenches with the same materials, said materials being the materials intended to form one among the first and second walls.

According to an embodiment, the method comprises thinning the substrate, from a second surface of the substrate, opposite to the first surface, to expose an end of the first or second trenches, the thinning being stopped before exposing ends of trenches having their materials filling the trenches.

According to an embodiment, the method comprises removing at least a portion of the materials in the exposed trenches and filling said trenches with the material of said one among the first and second walls.

According to an embodiment, the materials are totally removed except for an outer layer made of an electrically-insulating material.

According to an embodiment, the second walls have a height smaller than the height of the first walls.

According to an embodiment, the first walls have a height smaller than the height of the second walls.

According to an embodiment, the second walls are located in the active area.

According to an embodiment, the first walls separate the active area from a memory area.

According to an embodiment, the first walls comprise a core made of a conductive or semiconductor material and an outer layer made of an electrically-insulating material.

According to an embodiment, the second walls are made of materials reflecting radiation having a wavelength in the operating range of the photodiodes.

According to an embodiment, the device comprises a diffraction element in the active area.

According to an embodiment, the diffraction element is a resonance box comprising first elements extending in the active area from the first surface and second elements extending in the active area from the second surface.

According to an embodiment, the first elements are formed by the method of forming the second walls.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A shows a top view of an embodiment of an optoelectronic device;

FIG. 1B shows a cross-section view of the embodiment of FIG. 1A;

FIG. 2 shows a variant of the embodiment of FIG. 1A;

FIG. 3A shows the result of a step of manufacturing of the embodiment of FIG. 1;

FIG. 3B shows the result of another step of manufacturing of the embodiment of FIG. 1;

FIG. 3C shows the result of another step of manufacturing of the embodiment of FIG. 1;

FIG. 3D shows the result of another step of manufacturing of the embodiment of FIG. 1;

FIG. 4A shows a top view of another embodiment of an optoelectronic device;

FIG. 4B shows a cross-section view of the embodiment of FIG. 4A;

FIG. 5A shows a top view of another embodiment of an optoelectronic device; and

FIG. 5B shows a cross-section view of the embodiment of FIG. 5A.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than electric conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

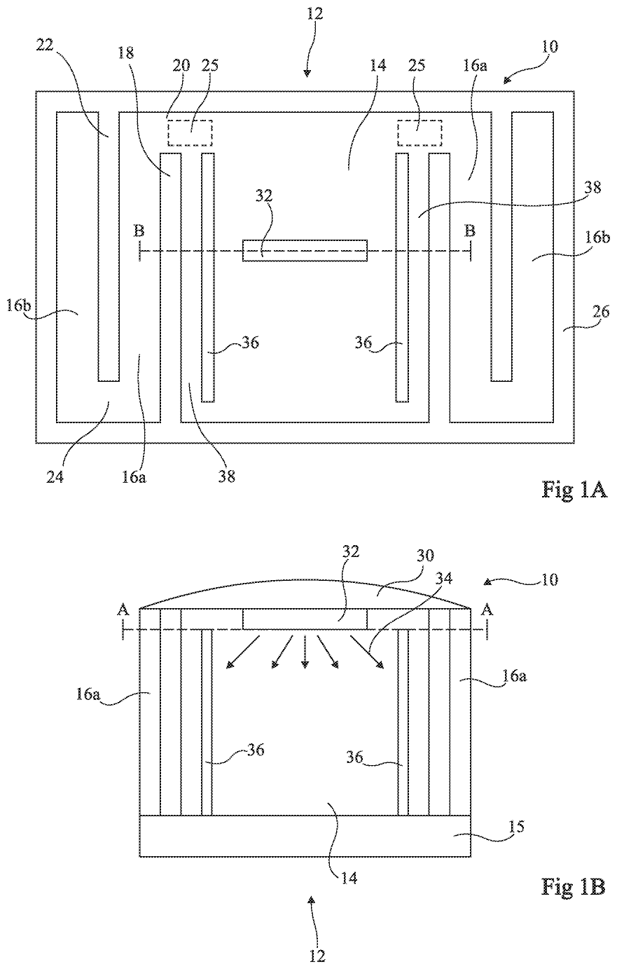

FIG. 1A shows a top view of an embodiment of an optoelectronic device. FIG. 1B shows a cross-section view of the embodiment of FIG. 1. More particularly, FIG. 1B shows a view along plane BB of FIG. 1A and FIG. 1A shows a view along plane AA of FIG. 1B.

The device comprises at least one pixel 10, preferably at least two pixels, a single one of which is shown in FIGS. 1A and 1B. Preferably, the device comprises a plurality of pixels arranged in an array.

Pixel 10 comprises a photosensor shown here as a photodiode 12. Photodiode 12 comprises an active area 14. The active area is, for example, formed in a semiconductor substrate. The active area is, for example, made of epitaxial silicon. The active area is, for example, formed on a layer 15. Layer 15 is made of a material having an optical index smaller than the optical index of the material of the active area. Preferably, layer 15 is made of an electrically-insulating material. Layer 15 at least partially reflects the radiation reaching the interface between active area 14 and layer 15. The radiation is thus confined in the active area.

Pixel 10 further comprises memory areas 16. Memory areas 16 enable the storage of charges during the charge generation phase. The memory areas are, for example, regions made of a semiconductor material, for example, of the same material as the active area.

In the example of FIG. 1, the shown pixel comprises four memory areas, divided in two assemblies of two memory areas. The two assemblies are located at the level of two opposite surfaces of the active area of the photodiode. The two assemblies of memory areas 16 are thus separated by active area 14. Each assembly of memory areas comprises a first memory area 16a. The first memory area is the area located closest to active area 14. The first memory area 16a of each assembly is separated from the active area by a conductive wall 18. Each conductive wall comprises an opening 20. Opening 20 is preferably at one end of wall 18. The active area and the first memory area are thus in contact at the level of opening 20. Each assembly comprises a second memory area 16b. Each second memory area is separated from the first memory area of the same assembly by a conductive wall 22, except for an opening 24. Opening 24 is preferably at one end of wall 22. Second memory area 16b and first memory area 16a are thus in contact at the level of opening 24.

Thus, during the charge detection phase, the charges are generated in the active area and the move to the first memory areas through openings 20 and then move to the second memory areas through openings 24.

The device, for example, comprises conductive elements 25 located above openings 20. Elements 25 are preferably biased to ease the movement of the charges in the memory area during the charge generation phase, and to limit the movement of the charges in the memory area during the readout phase.

As a variant, each pixel may comprise a different number of memory areas, for example, one or two memory areas.

Active area 14 and memory areas 16 are at least partially surrounded with a conductive wall 26. Conductive wall 26, for example, comprises openings, not shown. For example, wall 26 comprises an opening, preferably a single opening, in each memory area and in the active area.

The conductive walls each, for example, comprise a conductive or semiconductor core, not shown, for example, made of metal. The cores of the conductive walls are, for example, made of aluminum, of tungsten, of copper, or of polysilicon. The conductive walls preferably comprise an outer layer or sheath, not shown, made of an electrically-insulating material, for example, of silicon oxide. The conductive core of each wall is thus separated from the substrate, and more particularly from the memory areas and from the active area, by the outer layer. The conductive walls are buried capacitive structures (“Capacitive Deep Trench Insulation”—CDTI). The conductive walls indeed have an effect similar to that of a buried capacitor.

The interface between the conductive walls and active area 14 is thus an interface between the outer layer of the walls, preferably made of silicon oxide, and the active area, preferably made of silicon. The optical indices of silicon oxide and of silicon are different. The radiation present in the active area is thus partially reflected. The conductive walls thus partially optically insulate the active area from the neighboring pixels and from the memory areas, if the pixel comprises memory areas.

Because the outer layer is made of an electrically-insulating material, the conductive walls further enable to electrically insulate the active area from the neighboring pixels and from the memory areas, if the pixel comprises memory areas.

Preferably, the conductive walls extend along the entire height (thickness) of the active area. In the example of FIG. 1B, the conductive walls extend from layer 15 to the upper surface of the active area, that is, the surface which is not in contact with layer 15.

Like conductive elements 25, the conductive walls are preferably coupled to a voltage source. The walls are biased to form an electric field enabling to form areas 16 of the memory areas and to ease the movement of the charges in the memory areas during the charge generation phase, and so as to limit the movement of the charges in the memory area during the readout phase.

The device, for example, comprises lenses or filtering layers on the photodiodes. In the example of FIG. 1B, each photodiode is located opposite a lens 30 enabling to center the light radiation originating from the scene towards the active area.

The photodiode comprises a diffraction element 32. Diffraction element 32 is located in the active area. More particularly, the upper surface of the active area, that is, the surface closest to the scene, comprises a trench filled with a material having an optical index different from that of the active area, for example, filled with an electrically-insulating material. The shape of the trench and the material filling the trench are selected so that the radiation reaching diffraction element 32 is directed, as shown by arrows 34, in the entire active area. In particular, radiation may be directed towards walls 18, and thus towards the memory areas and towards the active areas of neighboring photodiodes. Radiation can thus be sent into regions of the active area, for example, peripheral regions, for example, regions close to wall 26, receiving few radiation. The diffraction element thus enables to increase the intensity of the radiation in the active area, the radiation reflecting on the conductive walls.

The trench, for example, has the shape of a triangular prism, and thus has a triangular cross-section in a cross-section view along a plane orthogonal to the planes of FIGS. 1A and 1B. In other words, the trench for example only has two surfaces in contact with the active area.

Diffraction element 32 preferably extends in the active area from the surface of the active area closest to lenses 30. The diffraction element preferably extends along a portion of the height of the active area, preferably along a height smaller than 25% of the height of the active area.

In the plane of FIG. 1A, that is, in top view, the dimensions of the diffraction element are smaller than the dimensions of the active area.

The pixel further comprises optical insulation walls 36. In the example of FIG. 1, each photodiode comprises two walls 36. The optical insulation walls are preferably located in the active area of the photodiode. Each wall 36 is located between the center of the active area and the memory areas. More particularly, each wall 36 is located between the diffraction element and one of walls 18. Preferably, each wall 36 is separated from the diffraction element by a region of active area 14, the distance between each wall 36 and the diffraction element being preferably at least 150 nm. Each wall 36 extends along (for example, parallel to but spaced apart from) at least a portion of one of walls 18. Each wall 36 is separated from the closest wall 18 by a region 38 of the active area. Preferably, region 38 extends along the entire length and the height of the associated wall 36. Thus, each wall 36 is not in contact with walls 18. The distance between each wall 36 and the closest wall 18 is preferably equal to substantially 150 nm.

Walls 36 extend from the lower surface of the active area, that is, the surface in contact with layer 15. Walls 36 extend towards the upper surface of the active area, preferably parallel to walls 18. Preferably, the ends of walls 36 closest to the upper surface of the active area are separated therefrom by a portion of the active area. Preferably, said end is separated from the upper surface of the active area by a distance at least equal to 0.2 μm. Preferably, walls 36 extend along at least 50% of the height of walls 18, preferably between 70% and 90% of the height of walls 18. Walls 18 preferably extending along the entire height of active area 14, walls 36 preferably extend along a height in the range from 70% to 90% of the height of the active area. Walls 36, for example, have a height substantially equal to 5.6 μm or 5.7 μm, the active area, and walls 18, for example having a height substantially equal to 6 μm.

As a variant, walls 36 may be located on the opposite side of wall 18. In other words, each wall 36 may be separated from the diffraction element by a wall 18, and may be separated from said wall 18 by region 38.

In the example of FIG. 1, walls 36 do not extend opposite openings 20, to allow for the movement of charges from the active area to the memory areas through openings 20.

Walls 36 are made of one or a plurality of materials enabling to optically insulate the active area from the memory areas and from the pixels close to pixel 10. For example, walls 36 are made of materials opaque to the wavelengths of the operating radiation of the photodiodes. In other words, walls 36 are opaque to radiation capable of causing the generation of charges in the photodiodes. Preferably, walls 36 are made of materials reflecting the radiation having as wavelengths the operating wavelengths of the photodiodes.

Walls 36 are, for example, made of an insulating material, for example, of silicon oxide, or of a material having a high dielectric constant, in other words a so-called “high-k” material. In the case where the material is a material having a high dielectric constant, and is not silicon oxide, each wall may comprise a layer made of an insulating material, for example, silicon oxide, surrounding a core made of a material having a high dielectric constant.

As a variant, walls 36 comprise a core made of an insulating material surrounded with a layer made of a semiconductor material, itself surrounded with a layer made of an insulating material. The insulating material is, for example, silicon oxide and the semiconductor material is, for example, polysilicon.

Thus, the radiation, in particular the radiation directed towards the memory areas by the diffraction element, can neither reach the memory areas nor the neighboring photodiodes. The radiation reaching the photodiode thus generates charges in the photodiode. The radiation reaching regions 38 of the active area of the photodiode are not directed by the diffraction element and are thus not generally directed towards the memory areas and the neighboring pixels. Further, the regions 38 unprotected by walls 36 form a small portion of the volume of the active area, preferably less than 18%, preferably less than 15% of the volume of the active area.

Pixels which do not comprise walls 36 could have been formed. However, the conductive walls only partially reflect the radiation, and part of the radiation would be directed outside of the active area and possibly into the neighboring photodiodes. Such radiation would then not be taken into account in the value of the pixel and would generate noise in the neighboring pixels and in the memory areas, if the pixel comprises memory areas.

It could have been devised to form walls replacing walls 18 and having the characteristics of walls 18 and 36, that is, a wall being conductive, that is, enabling to generate an electric field, and being optically insulating. However, no material is capable of optically insulating as well as wall 18 while allowing the generation of the electric field.

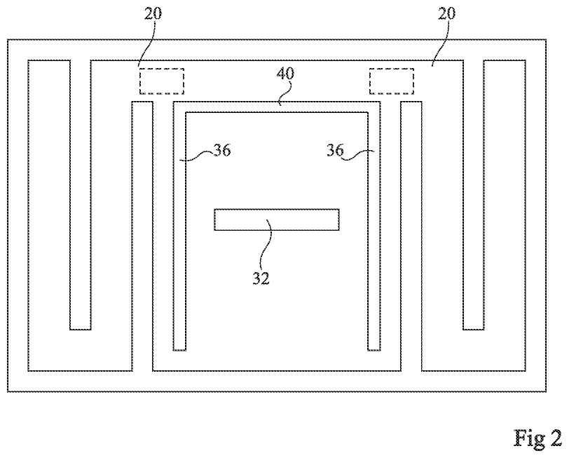

FIG. 2 shows a variant of the embodiment of FIG. 1A. More particularly, FIG. 2 shows a device similar to the device of FIG. 1A and of FIG. 1B. The device of FIG. 2 comprises all the elements of the device of FIGS. 1A and 1B, as previously described. The device of FIG. 2 differs from the device of FIGS. 1A and 1B by the shape of the optical insulation walls.

In FIG. 2, walls 36 are coupled by an optical insulation wall 40. Wall 40 extends from one wall 36 to the other. Wall 40 is thus in contact, by a first end, with a wall 36 and, by a second end, with the other wall 36. In the example of FIG. 2, the first end of wall 40 is in contact with an end of a wall 36, here the closest to openings 20, and the second end of wall 40 is in contact with one end of the other wall 36, here the end closest to openings 20. Walls 36 and 40 thus form a U-shaped wall. Diffraction element 32 is thus located inside of the U shape.

As a variant, wall 40 may be coupled to the other ends of walls 36, that is, the ends most remote from openings 20.

Wall 40 preferably has the same height as walls 36.

Wall 40 is made of the same materials as walls 36. Wall 40 is thus made of a material, preferably reflecting the operating wavelengths of the photodiodes.

As a variant, the walls may have a different shape. For example, wall 40 may comprise an opening. For example, wall 40 may be located at the same location as in the example of FIG. 2, but the dimensions of walls 36 and 40 may be such that the walls are not in contact. Walls 36 and 40 then form a U having openings at the level of its angles. The charges can then displace in the openings formed between the ends of walls 36 and 40.

For example, one or a plurality of other optical insulation walls, having the same characteristics as walls 36 and 40, may be formed in the active area of the photodiode.

The central portion of the active area, that is, the portion comprising the diffraction element, forms the most part of the active area, for example, more than 60% of the active area, and is not totally surrounded with the insulating wall, to allow the motion of charges.

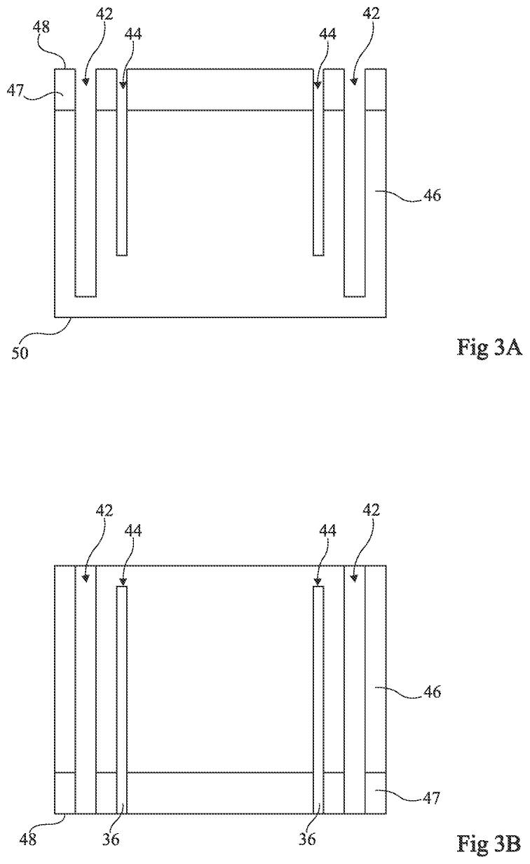

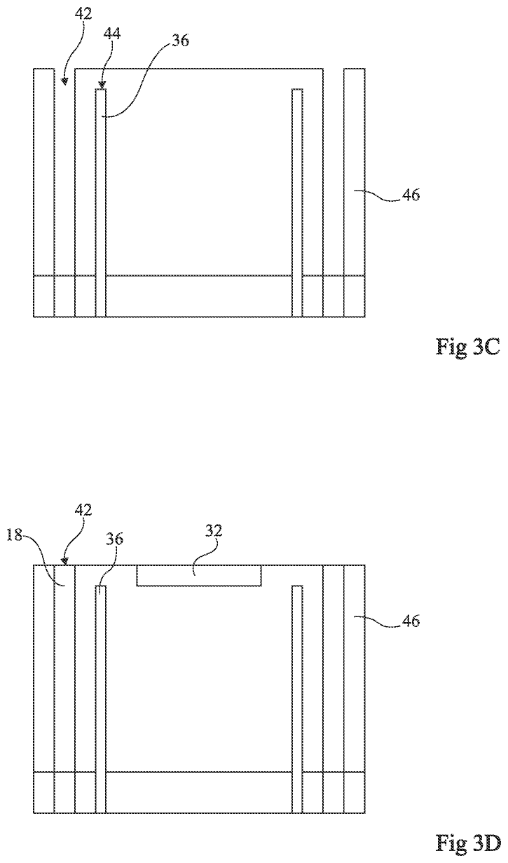

FIGS. 3A to 3D show results of successive steps of a method of manufacturing the device of FIGS. 1A and 1B or the device of FIG. 2. FIGS. 3A to 3D show cross-section views along plane BB of FIG. 1A.

FIGS. 3A to 3D do not show the forming of the entire pixel. In particular, FIGS. 3A to 3D do not show certain steps of forming of the photodiode, for example, the doping steps, and do not show the steps of forming of conductive vias and of metallizations, allowing a data transfer. The manufacturing of the elements which are not described may be carried out by known means capable of being deduced by those skilled in the art.

Further, FIGS. 3A to 3D only shows certain walls, walls 18 and 36. The other conductive walls 18 and 26 are, for example, formed in the same way as the shown walls 18. The other optical insulation walls 40 are formed in the same way as walls 36.

FIG. 3A shows the result of a step of manufacturing of the embodiment of FIG. 1.

During this step, trenches 42 and 44 are formed in a substrate 46. The depth of trenches 42 is substantially the same for all trenches 42. The depth of trenches 44 is substantially the same for all trenches 44. The depth of trenches 44 is smaller than the depth of trenches 42. Substrate 46 is preferably made of the material forming the active area of the photodiodes. Substrate 46 is preferably made of silicon. Substrate 46 is for example submitted to doping steps, which will not be described in detail, to form the photodiode.

Trenches 42 correspond to the conductive walls and trenches 44 correspond to the optical insulation walls. Thus, the shown trenches 42 are located at the locations of conductive walls 18. Trenches 42, not shown, are located at the locations of walls 22 and 26. The shown trenches 44 are located at the locations of walls 36. Other trenches 44 may be formed at the locations of other optical insulation walls.

The trench-forming step comprises the forming of a mask 47 on a surface 48 of the substrate. The mask is for example made of silicon nitride. The mask comprises openings at the level of trenches 42 and 44. The openings correspond to trenches 42 and 44 have different dimensions. More particularly, the width, that is, the smallest dimension of each opening, of the openings corresponding to trenches 42, is larger than the width of the openings corresponding to trenches 44. Thus, for a same opening length, the area of the opening is greater in the openings corresponding to trenches 42 than that in the openings corresponding to trenches 44. Preferably, the openings corresponding to trenches 44 have substantially the same width. Similarly, the openings corresponding to trenches 42 have substantially the same width.

Trenches 42 and 44 are then etched, through the openings of mask 47. Trenches 42 and 44 are etched during a same etch step, preferably during a single etch step. The etching is thus performed during a same time period in trenches 42 and 44.

The etch speed in the substrate depends on the size of the openings, and in particular on the width, that is, the smallest dimension. The smaller the etch surface area, that is, the area of the opening, the slower the etching. Thus, for a same etch time, trenches 42 and 44 have different depths. More particularly, trenches 44 are deeper than trenches 42. Trenches 42 have substantially a same depth. Trenches 44 have substantially a same depth.

The dimensions of the openings of mask 47, substantially corresponding to the dimensions of the opening of the trenches, are selected so that the depth difference between trenches 42 and 44 is sufficient for it to be possible to thin substrate 46 in planar fashion from surface 50, opposite to surface 48, and to reach the bottom of cavity 42, without reaching the bottom of trenches 44. The dimensions of the mask opening may thus depend on the etch technologies used. Preferably, the depth difference between trenches 42 and 44 is in the range from 200 nm to 800 nm, preferably substantially equal to 350 nm. Trenches 42, for example, have a depth in the range from 5.2 μm to 5.8 μm. Trenches 44, for example, have a depth in the range from 70% to 90% of the depth of trenches 42.

It could have been chosen to etch trenches 42 independently from trenches 44, for example, with different masks and during different manufacturing steps. However, it is preferable for walls 18 to be as close as possible to walls 36, and the independent forming of the trenches would cause trench alignment problems.

FIG. 3B shows the result of another step of manufacturing of the embodiment of FIG. 1.

During this step, trenches 42 and 44 are filled, preferably simultaneously, with the material(s) of walls 36.

The substrate is then flipped, to be able to reach surface 50. Steps, not shown, are carried out, for example, for the manufacturing of other components. Substrate 46 is then thinned in planar fashion, that is, each portion of surface 50 is thinned by substantially the same thickness. Substrate 46 is thinned to reach the bottom of trench 42. The substrate is thinned so as not to reach wall 36. The thinning thus does not reach the bottom of trenches 44. The thinning is thus stopped between the bottom of trenches 42 and the bottom of trenches 44. The bottom of trenches 44 is thus separated, by a substrate portion, from the surface area exposed at the end of the thinning.

FIG. 3C shows the result of another step of manufacturing of the embodiment of FIG. 1.

During this step, trenches 42 are emptied, preferably at least along the height of the active area of the photodiode, for example, at least along the entire height of the substrate.

Trenches 44 having not been exposed during the thinning, the material of walls 36 located in trenches 44 is not removed.

FIG. 3D shows the result of another step of manufacturing of the embodiment of FIG. 1.

During this step, trenches 42, emptied of the material of walls 36, are filled with the material of conductive walls 18.

In the case where the materials filling the trenches comprise an outer layer made of an insulating material, for example, of silicon oxide, it is possible not to remove the outer layer. This layer is then kept and becomes a portion of the conductive walls.

This step may also comprise the forming of other elements of the device, for example, the forming of diffraction element 32. The diffraction element then preferably has the shape of a parallelogram.

The step of FIG. 3A and the filling of the trenches described in relation with FIG. 3B form part of the steps of the so-called “back end of line” (BEOL) method. The rest of the step of FIG. 3B and the steps of FIGS. 3C and 3D form part of the so-called “front end of line” (FEOL) method. Thus, although trenches 42 and 44 are formed during a same step, the filling of walls 36 is performed during the BEOL steps and the filling of walls 18 is performed during the FEOL steps.

It could have been chosen to directly form walls 36 and 18, that is, to directly fill the trenches with the materials corresponding to walls 36 and 18 without filling trenches 42 with the material of walls 36. However, it is not possible to form walls 18 during the BEOL steps. Indeed, it is not possible to integrate metal during the FEOL steps, the thermal budget of the FEOL steps being too high. Further, the integration of metal would cause risks of crossed contamination of the substrate.

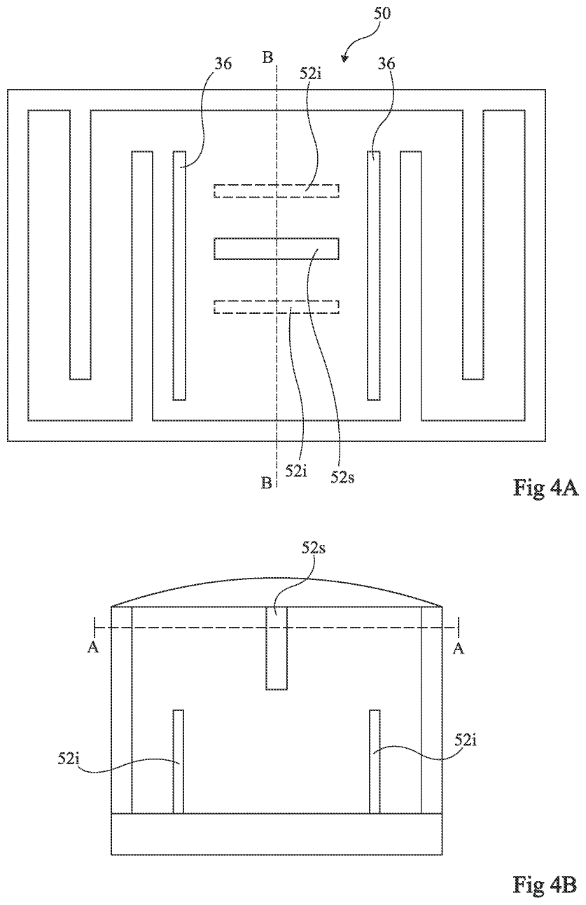

FIG. 4A shows a top view of another embodiment of an optoelectronic device. FIG. 4B shows a cross-section view of the embodiment of FIG. 4A. More particularly, FIG. 4B shows a view along plane BB of FIG. 4A and FIG. 4A shows a view along plane AA of FIG. 4B.

Device 50 is identical to the device of FIG. 1, except for the diffraction element, which is replaced with a plurality of diffraction elements 52. The diffraction elements are, like the element 32 of FIG. 1, located in the active area, between walls 36. The shape and the locations of the diffraction elements are selected so that the diffraction elements form a resonant grating or resonance box.

Each diffraction element 52 has, in the example of FIGS. 4A and 4B, the shape of a parallelogram. As a variant, diffraction elements 52, formed during the BEOL steps, may have another shape, for example, the shape of a triangular prism.

Diffraction elements 52 preferably extend in the direction from one wall 36 to the other wall 36. In other words, the main direction of diffraction elements 52 is preferably the direction from one wall 36 to the other wall 36. Main direction of the diffraction elements means the direction corresponding to the largest dimension among the dimensions other than the depth, that is, the dimensions in the top view (FIG. 4A).

Device 50 comprises two types of diffraction elements, upper elements 52s and lower elements 52i. Lower elements 52i are preferably parallel to one another. Upper elements 52s are preferably parallel to one another. Preferably, the lower elements are parallel to the upper elements.

Lower elements 52i, two of which are shown in FIGS. 4A and 4B, are for example made of the material of walls 36. Lower elements 52i extend from the lower surface of the active area. Lower elements 52i preferably extend from the same level as the lower end of walls 36. Lower elements 52i preferably extend along a height smaller than the height of the active area, preferably smaller than the height of walls 36.

The lower elements are preferably formed with walls 36. For example, during the step of FIG. 3A, third trenches are formed in the substrate, preferably through openings in the same mask 47. The third trenches are then filled with the material of walls 36. The openings corresponding to the third trenches are determined so that the third trenches may be formed during the same etch step as trenches 42 and 44. Elements 52 preferably having a height smaller than walls 36, the openings of the third trenches preferably have a surface area smaller than the openings corresponding to trenches 44, for example, a smaller width.

Upper elements 52s, one of which is shown in FIGS. 4A and 4B, are for example made of the material of walls 18. Upper elements 52s extend from the upper surface of the active area. Upper elements 52s preferably extend from the same level as the upper end of walls 36. Upper elements 52s preferably extend along a height smaller than the height of the active area, preferably smaller than the height of walls 36. Preferably, upper elements 52s have a same height as the lower elements. Preferably, the height of the upper and lower elements is smaller than half the height of the active area. The upper end of the lower elements thus does not reach the lower end of the upper elements. The diffraction elements, for example, have a height smaller than 280 nm. Elements 52s are preferably formed during the step of FIG. 3D, preferably after the forming of walls 18.

The number and the shape of diffraction elements 52 are selected to form a resonant grating. The presence of a resonant grating enables to improve the performance of the photodiode. Thus, the diffraction elements are preferably arranged in lines and have preferably parallel and distinct main directions. Preferably, each lower element is separated from the neighboring lower element by a same distance. Preferably, each upper element is separated from the neighboring upper element by a same distance, for example, equal to the distance separating two lower elements.

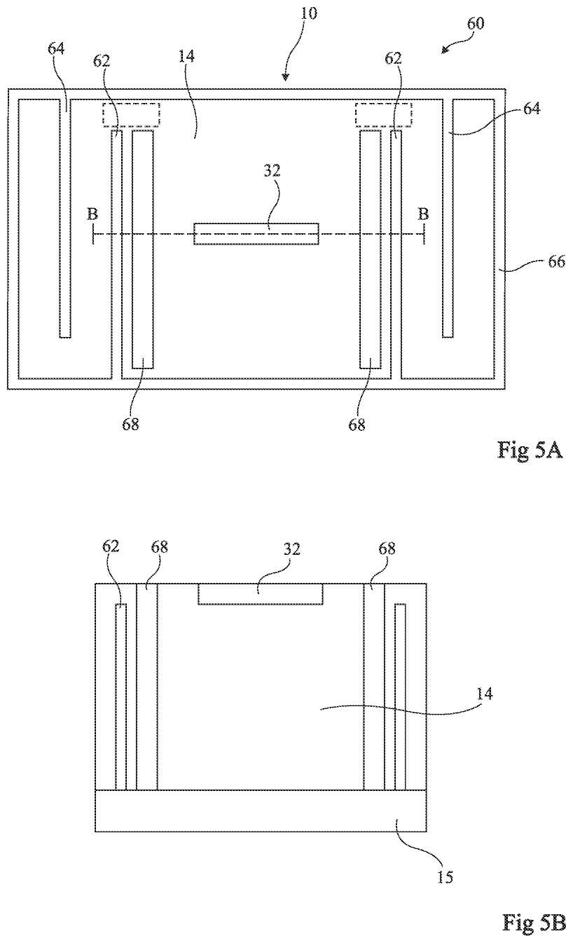

FIG. 5A shows a top view of another embodiment of an optoelectronic device 60. FIG. 5B shows a cross-section view of the embodiment of FIG. 5A.

Electronic device 60 is identical to the embodiment of FIGS. 1A and 1B, except for walls 18, 22, 26, and 36, which are respectively replaced, in the embodiment of FIGS. 5A and 5B, with walls 62, 64, 66, and 68.

Walls 62, 64, and 66 are conductive walls, as previously described, and are formed in the same way as walls 18, 22, and 26, that is, are made of the same materials as walls 18, 22, and 26, these materials being arranged in the same way. Thus, walls 62, 64, and 66 preferably comprise a conductive or semiconductor core separated from the semiconductor substrate by one or a plurality of insulating layers.

Further, walls 62, 64, and 66 carry out the same functions as walls 18, 22, and 26. Thus, walls 62, 64, and 66 are buried capacitive structures, the conductive core of which may be biased to generate an electric field. Further, at least one of the materials of walls 62, 64 and 66 has an optical index different from the optical index of the material of the active area enabling to partially reflect the radiation in the active area.

The material of wall 68 is the same material as wall 36. Thus, walls 68 are made of one or a plurality of materials enabling to optically insulate the active area from the memory areas and from the neighboring pixels of pixel 10. For example, walls 68 are made of materials opaque to the wavelengths of the operating radiation of the photodiodes. In other words, walls 68 are opaque to radiation capable of causing the generation of charges in the photodiodes. Preferably, walls 68 are made of materials reflecting radiation having as wavelengths the operating wavelengths of the photodiodes.

In the embodiment of FIGS. 5A and 5B, preferably, optical insulation walls 68, like the conductive walls 18 of FIGS. 1A and 1B, extend all along the height of the active area. In the example of FIGS. 5A and 5B, walls 68 extend from layer 15 to the upper surface of the active area, that is, the surface opposite to the surface in contact with layer 15.

Conductive walls 62, 64, 66, like the walls 36 of FIGS. 1A and 1B, extend from the lower surface of the active area, that is, the surface in contact with layer 15. Walls 62, 64, 66 extend towards the upper surface of the active area, preferably parallel to walls 68. Preferably, the ends of walls 62, 64, 66 closest to the upper surface of the active area are separated therefrom by a portion of the active area. Preferably, said end is separated from the upper surface of the active area by a distance at least equal to 0.2 μm. Preferably, walls 62, 64, 66 extend along at least 50% of the height of walls 68, preferably from 70% to 90% of the height of walls 68. Walls 68 preferably extending along the entire height of active area 14, walls 62, 64, 66 preferably extend along a height in the range from 70% to 90% of the height of the active area. Walls 62, 64, 66 for example have a height substantially equal to 5.6 μm or 5.7 μm, the active area, and walls 68, for example having a height substantially equal to 6 μm.

Further, the width of walls 68, that is, the smaller dimension in top view, is smaller than the width of walls 62, 64, and 66.

The manufacturing method of device 60 comprises steps similar to the steps of FIGS. 3A to 3D. The method of manufacturing of device 60 differs from FIGS. 3A to 3D in that, in the step corresponding to FIG. 3A, first openings in the mask opposite the locations of walls 68 have different dimensions than second openings in the mask opposite the locations of walls 62, 64, 66.

More particularly, the widths, the width corresponding to the smallest dimension of each opening, of the first openings are larger than the widths of the second openings. Thus, for a same opening length, the area of the opening is greater in the first openings than that in the second openings.

As previously described, the etch speed in the substrate depends on the size of the openings, and in particular on the width, that is, the smallest dimension. The smaller the etch surface area, that is, the area of the opening, the slower the etching. Thus, for a same etch duration, the trenches corresponding to walls 68 have different depths than the trenches corresponding to walls 62, 64, 66. More particularly, the trenches corresponding to walls 68 are deeper than the trenches corresponding to walls 62, 64, 66.

The dimensions of the openings of the mask, substantially corresponding to the dimensions of the opening of the trenches, are selected so that the depth difference between the trenches corresponding to walls 68 and the trenches corresponding to walls 62, 64, 66, is sufficient for it to be possible to thin substrate 46 in planar fashion from surface 50, opposite to surface 48, and to reach the bottom of the cavity corresponding to walls 68, without reaching the bottom of the trenches corresponding to walls 62, 64, 66. The dimensions of the mask openings may thus depend on the etch technologies used. Preferably, the depth difference between the trenches corresponding to walls 68 and the trenches corresponding to walls 62, 64, 66 is in the range from 200 nm to 800 nm, preferably substantially equal to 350 nm. The trenches corresponding to walls 68 for example have a depth in the range from 5.2 μm to 5.8 μm. The trenches corresponding to walls 62, 64, 66 for example have a depth in the range from 70% to 90% of the height of trenches 42.

The step corresponding to the step of FIG. 3B differs therefrom in that the trenches are filled with the materials of walls 62, 64, 66, that is, the materials of the conductive walls.

The step corresponding to the step of FIG. 3C differs therefrom in that the materials of walls 62, 64, 66 are removed from the trenches corresponding to walls 68 from the end each wall having being exposed. The trenches corresponding to walls 68 are then filled with the materials of walls 68.

The embodiment of FIGS. 5A and 5B and the embodiment of FIGS. 4A and 4B may be easily combined by those skilled in the art.

According to an embodiment, the photosensor (comprising a photodiode of as discussed above) can instead be implement as a SPAD (single-photon avalanche diode).

According to an embodiment, the pixel may not comprise any memory area 16. Neighboring pixels are separated by at least one wall comprising a metallic core and an optical insulation wall. Said walls, for example, extend on the entire length of the pixel, between the neighboring pixels.

According to an embodiment, the walls comprising a metallic core and the optical insulation walls have substantially the same dimensions. For example, said walls extend on the entire height of the photodiode or SPAD. For example, said walls have substantially the same width.

According to an embodiment, two neighboring pixel are separated by two optical insulation walls and a wall comprising a metallic core, the wall comprising a metallic core being situated between the optical insulation walls. Therefore, the photodiode or the SPAD of both neighboring pixels is separated from the wall comprising a metallic core by an optical insulation wall.

An example of a method of manufacturing this embodiment for example comprises the formation, from a first side of the substrate, of first cavities in a semiconductor substrate, for example in silicon at opposite sides of an active area. The first cavities are situated at the location of the optical insulation walls. The first cavities preferably extend through the entire height of the substrate, and the width of the first cavities is for example substantially equal to 200 nm. Next, the first cavities are filled by the optical insulation material of the optical insulation walls, for example said material is silicon oxide. From the first side of the substrate, formation of second cavities is made at the location of the wall comprising a metallic core. The second cavities are located adjacent and parallel to the first cavities. The second cavities preferably extend through the entire height of the substrate, the width of the second cavities is for example substantially equal to the width of the first cavities, for example 200 nm. The second cavities are then filled with a material that can be selectively etched in comparison with the material of the substrate and the material filling the first cavities, for example silicon nitride. Other steps from the front end of the line (FEOL), and the back end of the line (BEOL), including for example the formation of the photodiode or of the SPAD (in the active area between a pair of the first cavities filled with the optical insulation material), the thinning of the substrate, etc., may then be performed. Next, removal, from a second side of the substrate, of the material filling the second cavity is performed in order to reopen the second cavities. An insulating layer, for example in silicon oxide, is then formed on the flank of the reopened second cavities, with this insulating layer further extending on the face of the substrate on the second side. This is followed by the formation of a metallic layer filling the remainder of the reopened second cavities and covering over the insulating layer on the face of the substrate on the second side. Next, the metallic layer is, at least partially, removed from the face of the substrate on the second side.

According to an embodiment, two neighboring pixel are separated by an optical insulation wall and two walls comprising a metallic core, the optical insulation wall being situated between the walls comprising a metallic core. Therefore, the photodiode or the SPAD (i.e., the photosensor) of both neighboring pixels is separated from the optical insulation wall by a wall comprising a metallic core. An example of manufacturing method of this embodiment can be deduced by those skilled in the art based on the method described above.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An optoelectronic device, comprising:
at least one photosensor including:
an active area;
a first wall comprising a conductive core and an insulating sheath, said first wall including a first portion and a second portion; and
a second optical insulation wall extending parallel to said second portion of the first wall;
wherein at least a portion of an active area of said at least one photosensor is separated from a neighboring photosensor by the first portion of the first wall; and
wherein the portion of the active area is separated from the first memory area by the second portion of the first wall and the second optical insulation wall.

2. The device according to claim 1, wherein the second optical insulation wall has a height smaller than a height of the first wall.

3. The device according to claim 1, wherein the first wall has a height smaller than a height of the second optical insulation wall.

4. The device according to claim 1, wherein the second optical insulation wall is located in the active area.

5. The device according to claim 1, wherein the at least one photosensor further comprises a first memory area; wherein the first portion peripherally surrounds the at least one photosensor, and wherein the second portion extends perpendicularly from a side of the first portion and extends between the active area and the first memory area.

6. The device according to claim 5, wherein the at least one photosensor further comprises a second memory area, and wherein the first wall further includes a third portion; and
further comprising a third optical insulation wall extending parallel to said third portion of the first wall; wherein the portion of the active area is separated from the second memory area by the third portion of the first wall and the third optical insulation wall.

7. The device according to claim 6, wherein the at least one photosensor further comprises a fourth optical insulation wall connecting ends of the second and third optical insulation walls.

8. The device according to claim 7, wherein the first portion peripherally surrounds the at least one photosensor, and wherein the second and third portions extend perpendicularly from a first side of the first portion; and wherein the fourth optical insulation wall extends parallel to a second side of the first portion that is opposite the first side.

9. The device according to claim 1, wherein the second optical insulation wall is made of one or more materials which reflect radiation having a wavelength in an operating range of the at least one photosensor.

10. The device according to claim 1, further comprising a diffraction element in the active area.

11. The device according to claim 8, wherein the diffraction element is a resonance box comprising first elements extending in the active area from a first surface of the active area and second elements extending in the active area from a second surface of the active area.

12. The device according to claim 11, wherein the first elements are made of a same material as the second optical insulation wall.

13. The device according to claim 1, wherein the photosensor is a photodiode.

14. The device according to claim 1, wherein the photosensor is a single photon avalanche diode (SPAD).

15. A method of manufacturing an optoelectronic device including at least one photosensor having an active area, the method comprising:
forming a first wall and a second optical insulation wall, said first conductive wall including a first portion and a second portion,
wherein at least a portion of the active area of said at least one photosensor is separated from a neighboring photosensor by the first portion of the first wall; and
wherein the portion of the active area is separated from the first memory area by the second portion of the first wall and the second optical insulation wall extending parallel to the second portion.

16. The method according to claim 15, wherein forming comprises:
forming a first trench in a substrate, from a first surface of the substrate, at a location of the first wall; and
forming a second trench in the substrate, from the first surface of the substrate, at a location of the second optical insulation wall;
wherein forming the first and second trench is performed simultaneously.

17. The method according to claim 16, further comprising filling the first and second trenches with a same material, said material being a material for forming one of the first wall and the second wall.

18. The method according to claim 17, further comprising:
thinning the substrate, from a second surface of the substrate, opposite to the first surface, to expose an end of one of the first or second trenches, wherein thinning is stopped before exposing an end of the other of the first or second trench which is filled with said material.

19. The method according to claim 18, further comprising:
removing at least a portion of the material from the exposed end of the other of the first or second trench trenches; and
filling said the other of the first or second trench another material.

20. The method according to claim 19, wherein the material is totally removed except for an outer layer made of an electrically-insulating material.

21. The method according to claim 16, wherein the first trench has a different depth than the second trench.

22. The method according to claim 16, wherein the second trench is located in the active area.

23. The method according to claim 16, wherein a material filling the first trench comprises a core made of a conductive or semiconductor material and an outer layer made of an electrically-insulating material.

24. The method according to claim 16, wherein a material filling the second trench comprises a material for reflecting radiation having a wavelength in the operating range of the photodiodes.

25. The method according to claim 16, further comprising forming a diffraction element in the active area.

26. The method according to claim 25, wherein the diffraction element is a resonance box comprising first elements extending in the active area from the first surface and second elements extending in the active area from the second surface.

27. The method according to claim 26, wherein the first elements are formed by using a same process as is used for forming the second wall.

28. The method according to claim 16, wherein the photosensor is a photodiode.

29. The method according to claim 16, wherein the photosensor is a single photon avalanche diode (SPAD).

30. A method of manufacturing an optoelectronic device including at least one photosensor having an active area, the method comprising:
forming first cavities extending into a semiconductor substrate from a first side thereof at opposite sides of the active area;
filling the first cavities with an optical insulation material to form optical insulation walls;
forming second cavities extending into the semiconductor substrate from the first side thereof, said second cavities being located adjacent and parallel to the first cavities;
filling the second cavities with a sacrificial material that can be selectively etched in comparison with a material of the semiconductor substrate and the optical insulation material filling the first cavities;
forming a photosensor in the active area between pairs of first cavities filled with the optical insulation material;
removing the sacrificial material from a back side of the semiconductor substrate to reopen the second cavities;
forming an insulating material layer on side walls of the reopened second cavities; and
filling the reopened second cavities with a metallic layer to form a wall comprising a conductive core and an insulating sheath that separates said at least one photosensor from a neighboring photosensor.

31. The method of claim 30, where filling the reopened second cavities further comprises depositing said metallic layer on the back side of the semiconductor substrate.

32. The method of claim 31, further comprising partially removing the metallic layer on the back side.

33. The method of claim 30, wherein said first cavities extend completely through a height of the semiconductor substrate.

34. The method of claim 30, wherein said first cavities have a width substantially equal to 200 nm.

35. The method of claim 30, wherein the optical insulation material is silicon oxide.

36. The method of claim 30, wherein said second cavities extend completely through a height of the semiconductor substrate.

37. The method of claim 30, wherein said first and second cavities have substantially equal widths.

38. The method of claim 30, wherein the sacrificial material is silicon nitride.

39. The method of claim 30, further comprising, before removing the sacrificial material, thinning the semiconductor substrate from the back side.

40. The method of claim 30, wherein the insulating material layer is made of silicon oxide.

41. The method according to claim 30, wherein the photosensor is a photodiode.

42. The method according to claim 30, wherein the photosensor is a single photon avalanche diode (SPAD).
